(19) United States
(12) Patent Application Publication
(10) Pub. No.: US 2016/0181379 A1
(43) Pub. Date: Jun. 23, 2016

(54) SEMICONDUCTOR DEVICE AND METHOD FOR MANUFACTURING THE SAME

(71) Applicant: Mitsubishi Electric Corporation, Tokyo (JP)

(72) Inventor: Shinya AKAO, Tokyo (JP)

(73) Assignee: Mitsubishi Electric Corporation, Tokyo (JP)

(21) Appl. No.: 14/858,724

(22) Filed: Sep. 18, 2015

(30) Foreign Application Priority Data
Dec. 22, 2014 (JP) 2014-258436

(51) Int. Cl. H01L 29/417; H01L 29/06; H01L 21/324; H01L 21/285; H01L 21/288; H01L 29/78; H01L 29/45

(52) U.S. Cl. CPC H01L 29/41741; H01L 29/7813; H01L 29/0696; H01L 29/45; H01L 21/2855; H01L 21/288; H01L 21/324

(57) ABSTRACT

A semiconductor device includes: a semiconductor substrate; a plurality of trench gate electrodes that have a stripe shape in plan view and are located in parallel with each other at an interval; a gate insulating film located on surfaces of the trench gate electrodes; a first impurity layer located in an upper layer portion of the semiconductor substrate; a second impurity layer that is selectively located in a surface of the first impurity layer and is in contact with the gate insulating film; an interlayer insulating film that is located so as to cover upper portions of the trench gate electrodes and an upper portion of the second impurity layer, projects on the semiconductor substrate, and has a stripe shape in plan view; and a planarized buried film of metal that is buried in portions between projecting portions of the interlayer insulating film on the semiconductor substrate.

### BACKGROUND OF THE INVENTION

1. Field of the Invention

The present invention relates to a semiconductor device and more particularly to an improvement in a contact structure between a contact electrode through which a main current flows and a junction electrode in a power semiconductor device.

2. Description of the Background Art

In terms of global environmental conservation, power systems have been required to be reduced in size and to have high output to efficiently exploit energy, and power semiconductor devices (power devices) installed in the power systems have been required to increase a current density. Thus, improving thermal dissipation and reducing a resistance in an electrode junction have been required with the increase in the current density.

To achieve the purposes, the power device and more particularly, a vertical power device through which a main current flows vertically to a main surface of a semiconductor substrate has a structure that includes two main electrodes each connected to a contact electrode and includes the junction electrodes on the contact electrodes, the structure being gradually becoming standardized. The junction electrodes directly bond each of two main surfaces of the vertical power device to a lead frame and a heat spreader, so that the improved thermal dissipation and the reduced resistance in the electrode junction can be achieved.

Plating is used as a technique for forming the junction electrodes. In power devices such as a MOS field effect transistor (MOSFET) and an insulated gate bipolar transistor (IGBT), however, a main surface having a metal oxide semiconductor (MOS) structure has a great step height of an underlying layer, and a metal film in a process of laminating the contact electrode has poor coverage, resulting in “thinning” in which the contact electrode locally has a portion with a thin thickness and resulting in a greater step height on the surface.

When the junction electrode is formed on the contact electrode by the plating, the contact electrode is lost due to a chemical solution for the plating process. This destroys the MOS structure of the underlying layer and causes the plating solution to remain without the deposition of the metal film in the junction electrode, thereby reducing reliability of the bonding.

To solve the problems, for example, Japanese Patent Application Laid-Open No. 2008-28079 discloses a technology for forming a Ni plated film having a uniform thickness by electroless plating.

Japanese Patent Application Laid-Open No. 2008-28079 discloses the technology for reducing the size of a grain of an underlying film on which the Ni plated film is grown and making the underlying film having a specific crystal orientation to form the Ni plated film on the underlying film. However, the surface of the underlying film on which the Ni plated film is grown has the remains of a slight step height, as shown in FIG. 1 for example, and it is conceivable that a great degree of the remaining step height of the underlying film causes an uneven thickness of the underlying film.

### SUMMARY OF THE INVENTION

It is an object of the present invention to provide a semiconductor device in which reliability of an electrode junction is improved by forming a plating film having a uniform thickness.

A semiconductor device includes: a semiconductor substrate; a plurality of trench gate electrodes that reach the inside of the semiconductor substrate from one main surface of the semiconductor substrate, have a stripe shape in plan view, and are located in parallel with each other at an interval; a gate insulating film located on surfaces of the trench gate electrodes; a first impurity layer located in an upper layer portion of the semiconductor substrate; a second impurity layer that is selectively located in a surface of the first impurity layer and is in contact with the gate insulating film; an interlayer insulating film that is located so as to cover upper portions of the trench gate electrodes and an upper portion of the second impurity layer, projects on the semiconductor substrate, and has a stripe shape in plan view; a planarized buried film of metal that is buried in portions between projecting portions of the interlayer insulating film on the semiconductor substrate and has an upper surface planarized; a contact electrode located on the planarized buried film; and a junction electrode located on the contact electrode.

The semiconductor device includes the planarized buried film that is buried in the portions between the projecting portions of the interlayer insulating film on the semiconductor substrate and has the upper surface planarized, so that “thinning” of the contact electrode is suppressed to make the thickness uniform and the reliability of the electrode junction is improved.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a perspective view showing a partial structure of a trench-gate MOS transistor according to a preferred embodiment;

FIGS. 2 to 10 are perspective views showing steps of manufacturing the trench-gate MOS transistor according to the preferred embodiment;

FIG. 11 is a diagram showing a state in which the trench-gate MOS transistor according to the preferred embodiment is installed in a semiconductor device module;

FIG. 12 is a cross-sectional view showing a partial structure of the trench-gate MOS transistor;

FIG. 13 is a cross-sectional view showing a stage in which a contact electrode has been formed;

FIG. 14 is a cross-sectional view showing a stage in which the contact electrode has been etched;

FIG. 15 is a cross-sectional view showing a state in which a junction electrode and an oxidation preventing film have been formed by plating while losing the contact electrode; and

FIG. 16 is a cross-sectional view showing a state in which a semiconductor device with a partial loss of the contact electrode is installed in the semiconductor device module through the junction electrode.

### DESCRIPTION OF THE PREFERRED EMBODIMENT

<Introduction>

Prior to descriptions of the preferred embodiment according to the present invention, problems in forming a contact electrode in a typical vertical power device are described.

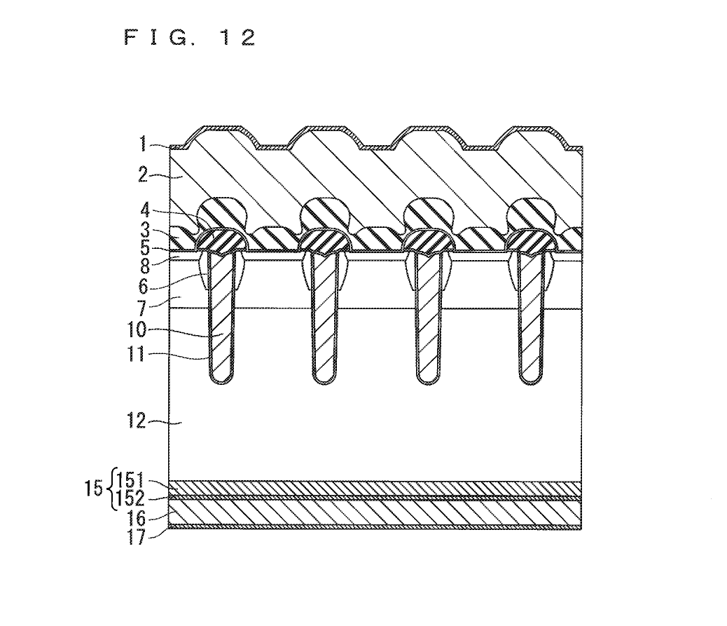

FIG. 12 is a cross-sectional view showing a partial structure of a trench-gate MOS transistor. In addition, the MOS transistor is described as an N-channel MOS transistor. As shown in FIG. 12, an impurity layer 7 of a P-type (body region) is provided on one main surface (upper main surface) of a semiconductor substrate 12 of an N-type, and an impurity layer 8 of a P-type (contact region) is selectively provided in a surface of the impurity layer 7. A plurality of trench gate electrodes 10 are provided to penetrate the impurity layer 8 and the impurity layer 7 so as to reach the inside of the semiconductor substrate 12.

A gate oxidation film 11 (gate insulating film) covers surfaces of the trench gate electrodes 10, and an impurity layer 6 of an N-type (source region) is provided outside the gate oxidation film 11. The impurity layer 6 is provided to penetrate the impurity layer 8 so as to have a depth that reaches the inside of the impurity layer 7 and is in contact with the gate oxidation film 11 being the side of the trench gate electrode 10.

A contact interlayer insulating film 4 is provided so as to cover upper portions of the trench gate electrodes 10, an upper portion of the impurity layer 6, and an upper portion of a region in contact with the impurity layer 6 and the impurity layer 8. A barrier metal 5 is provided so as to cover surfaces of the contact interlayer insulating film 4 and the impurity layer 8.

A contact electrode 3 is provided so as to cover an entire surface of the harrier metal 5. A junction electrode 2 is provided so as to cover an entire surface or part of the surface of the contact electrode 3. An oxidation preventing film 1 is provided so as to cover an entire surface of the junction electrode 2. The contact electrode 3 and the junction electrode 2 form a main electrode, but only the contact electrode 3 may form the main electrode.

A metal film 151 is provided on the other main surface (lower main surface) of the semiconductor substrate and a metal film 152 is provided on an entire surface of the metal film 151, to thereby form a contact electrode 15 having the multiple layers. A junction electrode 16 is provided on an entire surface of the metal film 152, and an oxidation preventing film 17 is provided on an entire surface of the junction electrode 16. The contact electrode 15 and the junction electrode 16 form a main electrode, but only the contact electrode 15 may form the main electrode.

Here, the oxidation preventing films 1, 17 are made of any of gold (Au), silver (Ag), palladium (Pd), and titanium (Ti) or formed of a laminated film thereof. The junction electrodes 2, 16 are made of nickel (Ni) or copper (Cu). The contact electrode 3 is made of any of aluminum (Al), AlSi, AlSiCu, and AlCu. The contact interlayer insulating film 4 is made of any of a thermal oxidation film of silicon, tetra ethyl orthosilicate (TEOS), boro-phospho tetra ethyl orthosilicate (BP-TEOS), and boro-phospho silicate glass (BPSG).

The barrier metal 5 is made of Ti silicide or cobalt (Co) silicide. The trench gate electrodes 10 are made of polysilicon. The contact electrode 15 is formed of a laminated film or a single-layer film selected from Al, AlSi, AlCu, AlSiCu, Ti, and vanadium (V).

The semiconductor substrate 12 may be a silicon substrate or a silicon carbide (SiC) substrate.

In a case where the semiconductor substrate 12 is an N-type silicon substrate, the impurity layer 6 is formed as an N-type impurity layer by implantation and activation of a relatively high concentration of phosphorus (P) or arsenic (As), the impurity layer 7 is formed as a P-type impurity layer by implantation and activation of boron (B), the impurity layer 8 is formed as a P-type impurity layer by implantation and activation of a higher concentration of B than that in the impurity layer 7, and the trench gate electrodes 10, the gate oxidation film 11, and the impurity layers 6 to 8 form a MOS structure.

Here, the contact electrodes 3, 15 join the semiconductor device to the junction electrodes with a low loss (low resistance) and can efficiently dissipate heat generated in the semiconductor device. Moreover, the contact electrodes 3, 15 are made of a material having strong adhesion to both of the semiconductor device and the junction electrodes to the extent that the contact electrodes 3, 15 do not peel off due to thermal stress in the actual operation or upon mounting.

The junction electrodes 2, 16 join junction components of a module that install the contact electrodes and the semiconductor device to the semiconductor device with a low loss (low resistance) and can efficiently dissipate heat generated in the semiconductor device. Moreover, the junction electrodes 2, 16 are made of a material having strong adhesion to both of the contact electrodes and the junction components of the module to the extent that the junction electrodes 2, 16 do not peel off due to thermal stress in the actual operation or upon mounting.

The contact electrode 3 is formed by a physical technique, such as sputtering and physical vapor deposition (PVD) and formed on a surface of the underlying layer having a great step height due to the MOS structure and the contact structure.

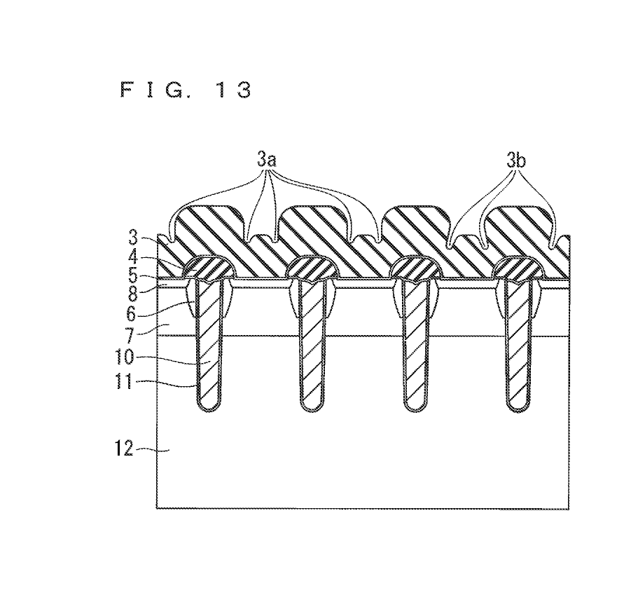

Here, FIG. 13 is a cross-sectional view showing a stage in which the contact electrode 3 has been formed during the manufacturing step. As shown in FIG. 13, the contact electrode 3 has thin-walled portions 3a and 3b in which the thickness is locally thin by “thinning.” The “thinning” is more noticeable in thin-walled portions 3b than the thin-walled portions 3a.

In this structure, the junction electrode 2 and the oxidation preventing film 1 are formed on the contact electrode 3 by plating, such as electroless plating and electric field plating. In the plating, a surface layer of the contact electrode 3 is cleaned by etching using an acid or alkaline chemical solution before plating, and zincate treatment is performed to inhibit oxidation of the contact electrode 3 (Al or an alloy of Al) that has been cleared.

The zincate treatment is treatment that removes an oxidation film of Al formed on a surface of Al or an alloy of Al and forms a coating of zinc (Zn). Specifically, when Al or the alloy of Al is immersed in an aqueous solution in which Zn as an ion is dissolved, Al as an ion is dissolved because Zn has a higher standard oxidation-reduction potential than that of Al, and an electron generated at this time causes the Zn ion to gain an electron on the surface of Al or the alloy of Al to form the coating of Zn on the surface of Al. Also at this time, the oxidation film of Al is removed. Subsequently, Al or the alloy of Al coated with Zn is immersed in a concentrated nitric acid to dissolve Zn, and a thin and uniform oxide coating of Al is formed on the surface of Al. Then, Al or the alloy of Al is immersed in the Zn treatment solution again to coat the surface of Al or the alloy of Al with Zn, and the oxidation film of Al is removed. This operation causes the oxidation film of Al to be thin and smooth.

Subsequently, electroless Ni plating, for example, is performed to form the junction electrode 2. In other words, Al or the alloy of Al coated with Zn is immersed in an electroless Ni plating solution, and Ni is deposited on Al or the alloy of Al at first because Zn has a lower standard oxidation-reduction potential than that of Ni. The surface continues to be coated with Ni, and Ni is deposited by automatic catalysis caused by an action of a reducing agent included in the plating solution, to thereby form the junction electrode 2.

The contact electrode 3 has a thickness of approximately 0.3 μm to 0.5 μm on average reduced by etching in the above-mentioned plating pretreatment. When the contact electrode 3 has poor coverage and partially has a thin thickness or has different grains as in the thin-walled portions 3a and 3b shown in FIG. 13, the etching with an etching solution of sulfuric acid or nitric acid moves faster, resulting in a loss of the portion of the contact electrode 3.

In the plating pretreatment, an etching solution in which an oxidizing agent is mixed with a fluoride is also used, so that when the contact electrode 3 is partially lost, the oxide film, the polysilicon film, and the silicon substrate below the lost portion are etched by the fluoride such as hydrofluoric acid. As a result, not only the contact electrode 3 is partially lost, but also the semiconductor substrate 12 being the lower layer is partially lost.

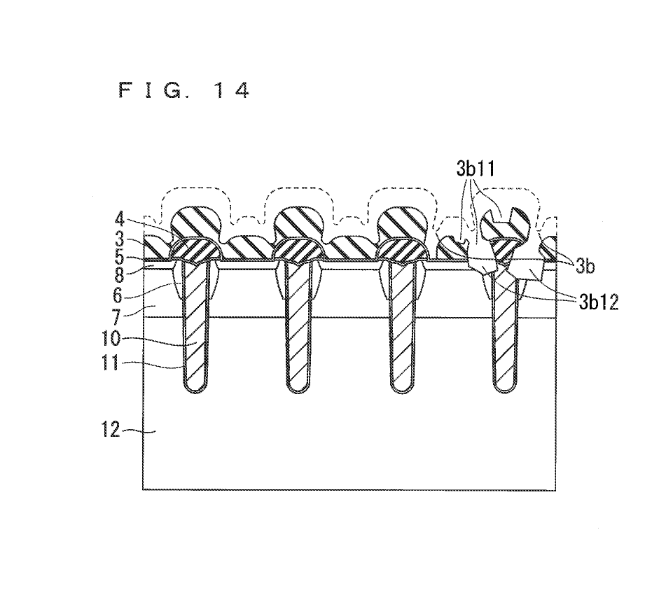

FIG. 14 is a cross-sectional view showing a stage in which the contact electrode 3 has been etched during the manufacturing step. The contact electrode 3 immediately after the formation shown in FIG. 13 is indicated by a broken line in FIG. 14, and it is clear that the portions corresponding to the thin-walled portions 3b suffer from a noticeable loss.

In other words, it is clear that normal irregularities of approximately 0.3 μm to 3.0 μm are formed in the contact electrode 3 after etching, and large hollow portions 3b12 through the barrier metal 5, the contact interlayer insulating film 4, the trench gate electrode 10, and the semiconductor substrate 12 are also formed in the portions corresponding to the thin-walled portions 3b in which the coverage is poor and the “thinning” is noticeable in the contact electrode 3 after etching.

It is clear that local recessed portions 3b 11 are formed in the portions of the contact electrode 3 having the different grains caused by different etching rates.

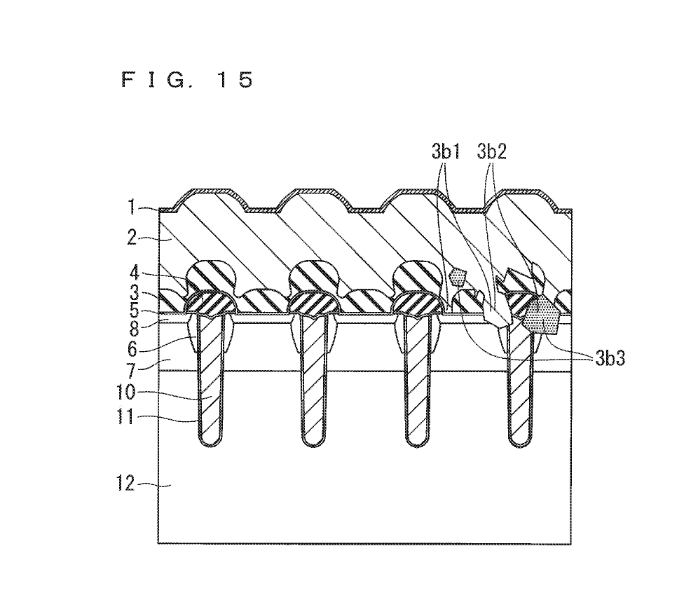

FIG. 15 is a cross-sectional view showing a state in which the junction electrode 2 and the oxidation preventing film 1 have been formed by plating while losing the contact electrode 3 as shown in FIG. 14.

In portions 3b 1 shown in FIG. 15, a resistance value of a contact resistance is not a normal value because the junction electrode 2 is directly formed by the plating in the structure below the barrier metal 5. Thus, the MOS structure formed of the impurity layers 6, 7, 8 fails to function normally, so that the semiconductor device fails to operate normally.

In portions 3b2 shown in FIG. 15, the structure below the barrier metal 5 is lost by etching with the etching solution for the plating pretreatment or with the plating solution itself, so that the semiconductor device fails to operate normally.

In portions 3b3 shown in FIG. 15, the plating solution is collected inside the junction electrode 2 and the semiconductor device, so that the semiconductor device fails to operate normally. The plating solution collected is vaporized by subsequent heat treatment at a high temperature such as soldering, thereby hampering normal bonding and reducing reliability of the bonding.

A crystal surface of the grain also causes a difference in deposition speed of a plating material, possibly resulting in the portions 3b1 to 3b3.

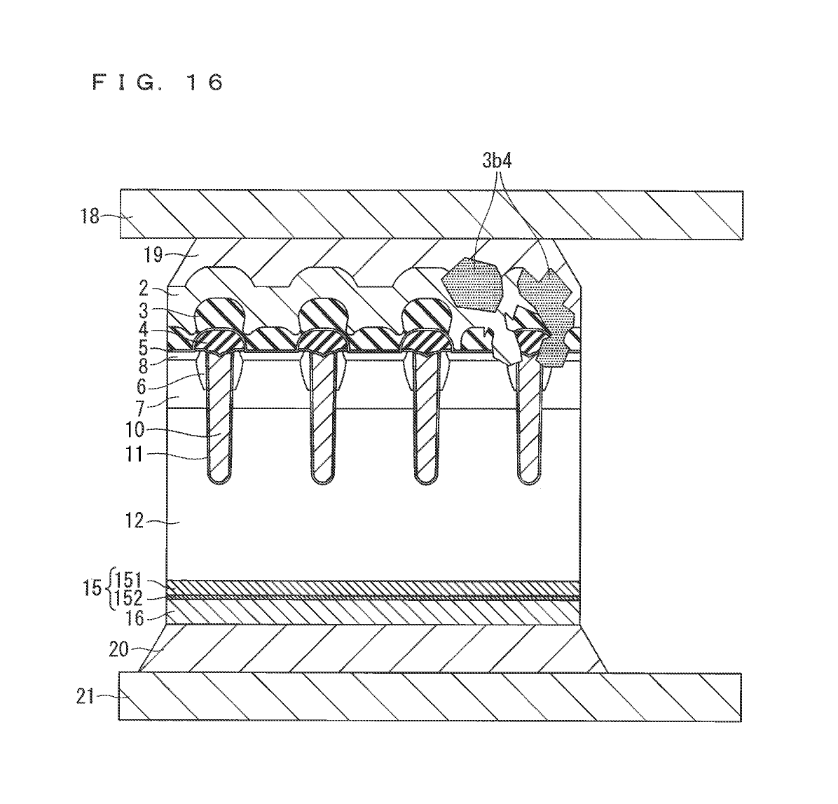

FIG. 16 is a cross-sectional view showing a state in which the semiconductor device with the partial loss of the contact electrode 3 shown in FIG. 15 is installed in a semiconductor device module through the junction electrode 2.

As shown in FIG. 16, the junction electrode 2 and the junction electrode 16 are respectively bonded to a junction electrode 18 and a junction electrode 21 of the semiconductor device module through a solder layer 19 and a solder layer 20, the junction electrodes 18, 21 being opposite to the junction electrodes 2, 16, respectively. The oxidation preventing film 1 on the junction electrode 2 is lost by the bonding, and the junction electrode 2 also has the thickness reduced by the bonding. The same applies to the junction electrode 16 and the oxidation preventing film 17.

In a case where the semiconductor module is bonded from the junction electrode 2 side, stress acting on the inside of the contact electrode 3 due to mechanical and thermal factors from the module side causes a contact structure at the bottom of the contact electrode 3 to be affected by an anchor effect, thereby reducing the reliability of the bonding.

In other words, the impurity layer 8 in contact with the bottom of the contact electrode 3 is a contact region between the contact electrode 3 and the semiconductor substrate 12, and the contact region includes the contact interlayer insulating film 4 as a projecting portion on both sides while the bottom of the contact electrode 3 is seemingly bonded to the surface having the large irregularities.

The anchor effect is an effect of increasing adhesion by irregularities of an adhesive surface that increases an effective area for bonding. The contact region (recessed portion) is in a state as if the contact region is hammered by a stake into the structure above the contact electrode 3, and the contact interlayer insulating film 4 (projecting portion) is thus engaged in the contact electrode 3. Thus, when the contact electrode 3 slides in a horizontal direction by stress or the like, the stress in the horizontal direction is concentrated, thereby affecting the contact structure.

Moisture in the plating solution collected being the portions 3b3 shown in FIG. 15 is vaporized by the heat treatment upon soldering and the solder is repelled, which results in portions 3b4 shown in FIG. 16, the portions 3b4 being faulty junctions. The faulty junctions increase a contact resistance and degrade thermal dissipation, thereby further reducing the reliability of the bonding.

The oxidation preventing film 1 on the junction electrode 2 is a film for preventing oxidation of the junction electrode 2 and thus needs to completely cover the surface of the junction electrode 2. Platinum (Pt), Pd, Au, or Ag or a laminated film thereof is used tor the oxidation preventing film 1, Pt, Pd, Au, and Ag being rare metal materials that are hardly oxidized, and larger irregularities on the surface of the junction electrode 2 make the required thickness thick. This degrades wetting and spreading of solder to reduce an assembly yield and also increases a manufacturing cost.

In this manner, it has been difficult to form the plating film having the uniform thickness in the vertical power device including the trench gate electrodes.

<Preferred Embodiment>

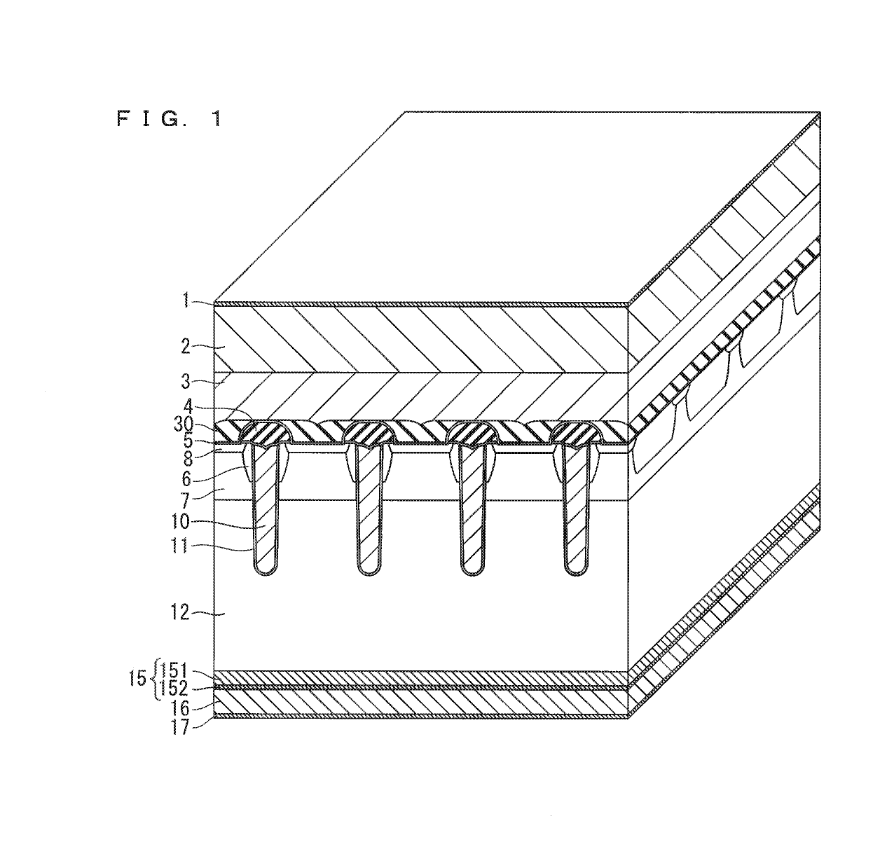

Hereinafter, a semiconductor device in a preferred embodiment according to the present invention is described with reference to FIGS. 1 to 11.

<Device Configuration>

FIG. 1 is a perspective view showing a partial structure of a trench-gate MOS transistor 100 according to the preferred embodiment. In addition, the MOS transistor is described as an N-channel MOS transistor, but application of the present invention may be a P-channel MOS transistor, or may be an IGBT without being limited to the MOS transistor. A collector layer of a P-type is provided on a lower main surface side of a semiconductor substrate 12, which is an N-channel IGBT. That is to say, a device that includes a trench gate electrode whose upper portion is covered with an interlayer insulating film and projects is applicable.

As shown in FIG. 1, in the trench-gate MOS transistor 100, an impurity layer 7 of a P-type (body region) is provided on one main surface (upper main surface) side of the semiconductor substrate 12 of an N-type, and an impurity layer 8 of a P-type (contact region) is selectively provided in a surface of the impurity layer 7. A plurality of trench gate electrodes 10 are provided to penetrate the impurity layer 8 and the impurity layer 7 so as to reach the inside of the semiconductor substrate 12.

A gate oxidation film 11 covers surfaces of the trench gate electrodes 10, and an impurity layer 6 of an N-type (source region) is provided outside the gate oxidation film 11. The impurity layer 6 is provided to penetrate the impurity layer 8 so as to have a depth that reaches the inside of the impurity layer 7 and is in contact with the gate oxidation film 11 being the side of the trench gate electrode 10.

A contact interlayer insulting film 4 is provided so as to cover upper portions of the trench gate electrodes 10, an upper portion of the impurity layer 6, and an upper portion of a region in contact with the impurity layer 6 and the impurity layer 8. A barrier metal 5 is provided so as to cover surfaces of the contact interlayer insulating film 4 and the impurity layer 8. The contact interlayer insulating film 4 is formed for electrically insulating the trench gate electrodes 10 from a contact electrode 3.

A planarized buried film 30 is provided so as to cover an entire surface of the barrier metal 5. The planarized buried film 30 is buried in portions between projecting portions of the contact interlayer insulating film 4 on the semiconductor substrate 12, which planarizes the upper surface and resolves the irregularities due to the contact interlayer insulating film 4.

The contact electrode 3 is provided so as to cover an entire surface of the planarized buried film 30. A junction electrode 2 is provided so as to cover an entire surface of the contact electrode 3. An oxidation preventing film 1 is provided so as to cover an entire surface of the junction electrode 2. The contact electrode 3 and the junction electrode 2 form a main electrode, but only the contact electrode 3 may form the main electrode.

A metal film 151 is provided on the other main surface (lower main surface) of the semiconductor substrate 12, and a metal film 152 is provided on an entire surface of the metal film 151, to thereby form a contact electrode 15 having the multiple layers. A junction electrode 16 is provided on an entire surface of the metal film 152, and an oxidation preventing film 17 is provided on an entire surface of the junction electrode 16. The contact electrode 15 and the junction electrode 16 form a main electrode, but only the contact electrode 15 may form the main electrode.

Here, the oxidation preventing films 1, 17 are made of any of Au, Ag, Pd, and Ti, or formed of a laminated film thereof. The junction electrodes 2, 16 are made of Ni or Cu. The contact electrode 3 is made of any of Al, AlSi, AlSiCu, and AlCu. The contact interlayer insulating film 4 is made of any of a thermal oxidation film of silicon, TEOS, BP-TEOS, and BPSG.

The barrier metal 5 is made of Ti silicide or Co silicide. The trench gate electrodes 10 are made of polysilicon. The contact electrode 15 is formed of a laminated film or a single-layer film selected from Al, AlSi, AlCu, AlSiCu, Ti, and V.

The planarized buried film 30 is made of any of tungsten (W), Al, AlSi, AlSiCu, and AlCu, and may be formed of the same material as that of the contact electrode 3.

The semiconductor substrate 12 may be a silicon substrate, a SiC substrate, or a substrate including a wide band gap semiconductor except for SiC.

In a case where the semiconductor substrate 12 is an N-type silicon substrate, the impurity layer 6 is formed as an N-type impurity layer by implantation and activation of a relatively high concentration of P or As, the impurity layer 7 is formed as a P-type impurity layer by implantation and activation of B, the impurity layer 8 is formed as a P-type impurity layer by implantation and activation of a higher concentration of B than that in the impurity layer 7, and the trench gate electrodes 10, the gate oxidation film 11, and the impurity layers 6 to 8 form a MOS structure.

In addition, the impurity layer 8 is a high-concentration impurity region and a contact region that contributes to a reduction in a contact resistance with a configuration of an upper layer.

As described above, in the trench-gate MOS transistor 100, the planarized buried film 30 is buried in the portions between the projecting portions of the contact interlayer insulating film 4 on the semiconductor substrate 12, which planarizes the upper surface and resolves the irregularities due to the contact interlayer insulating film 4. Thus, the contact electrode 3 can be easily formed to have a thickness (for example, 3 μm or more) sufficiently thicker than a thickness reduced by etching upon plating pretreatment and formed to be uniform (step height of irregularities is 2.0 μm or less) without occurrence of the “thinning.”

As a result, direct bonding of the junction electrode 2 to the semiconductor substrate 12 caused by the partial loss of the contact electrode 3 and erosion of the MOS structure by an etching solution or a plating solution upon the plating pretreatment are prevented, to thereby resolve the problems that the semiconductor device fails to operate normally, the plating solution collected in the junction electrode 2 hampers normal bonding to reduce the reliability of the bonding, and localized stress causes to reduce the reliability of the bonding.

<Manufacturing Method>

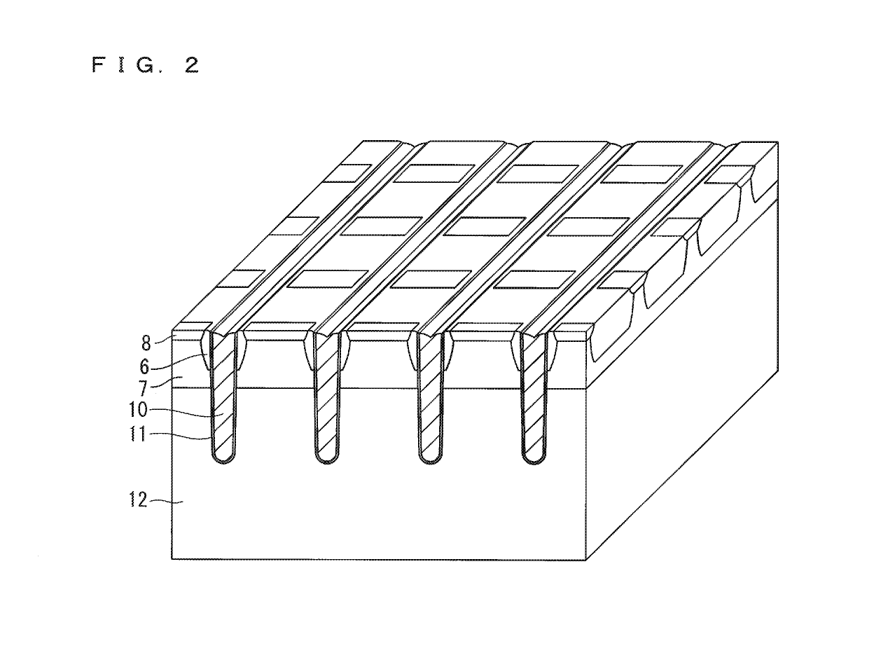

Next, a method for manufacturing the trench-gate MOS transistor 100 is described with reference to FIGS. 2 to 10 that are perspective views showing manufacturing steps in order. In addition, a conventional technique can be basically used as the manufacturing method, so that specific formation conditions are omitted.

In a step shown in FIG. 2, the semiconductor substrate 12 is prepared, and after B is ion-implanted to the one main surface of the semiconductor substrate 12 to form the impurity layer 7, B is ion-implanted to the impurity layer 7 to form the impurity layer 8. Subsequently, P or As is selectively ion-implanted from above the impurity layer 8 to selectively form the impurity layer 6. In this case, the impurity layer 6 is formed with a depth shallower than that of the impurity layer 7, and the impurity layer 8 is formed with a depth shallower than that of the impurity layer 6. The impurity layer 6 and the impurity layer 8 are alternately arranged in parallel in a stripe shape in the main surface of the semiconductor substrate 12, and the impurity layer 6 is provided so as to extend to the impurity layer 8 side from the portion of the stripe shape such that the impurity layer 8 sandwiches part of the impurity layer 6, so that the impurity layer 6 serves as a source region capable of providing a common potential.

Next, a plurality of trenches are formed to penetrate the impurity layer 8 and the impurity layer 7 and to reach the inside of the semiconductor substrate 12. After the gate oxidation film 11 is formed inside the trenches, a polysilicon film is formed on an entire upper main surface of the semiconductor substrate 12 by, for example, chemical vapor deposition (CVD) to fill the plurality of trenches with the polysilicon film, to thereby form the gate electrodes 10.

Subsequently, an excess polysilicon film on the semiconductor substrate 12 is removed to obtain the configuration shown in FIG. 2. The plurality of gate electrodes 10 are formed to extend in a direction orthogonal to a direction in which the impurity layers 6, 8 extend, and the gate electrodes 10 also penetrate the impurity layer 8.

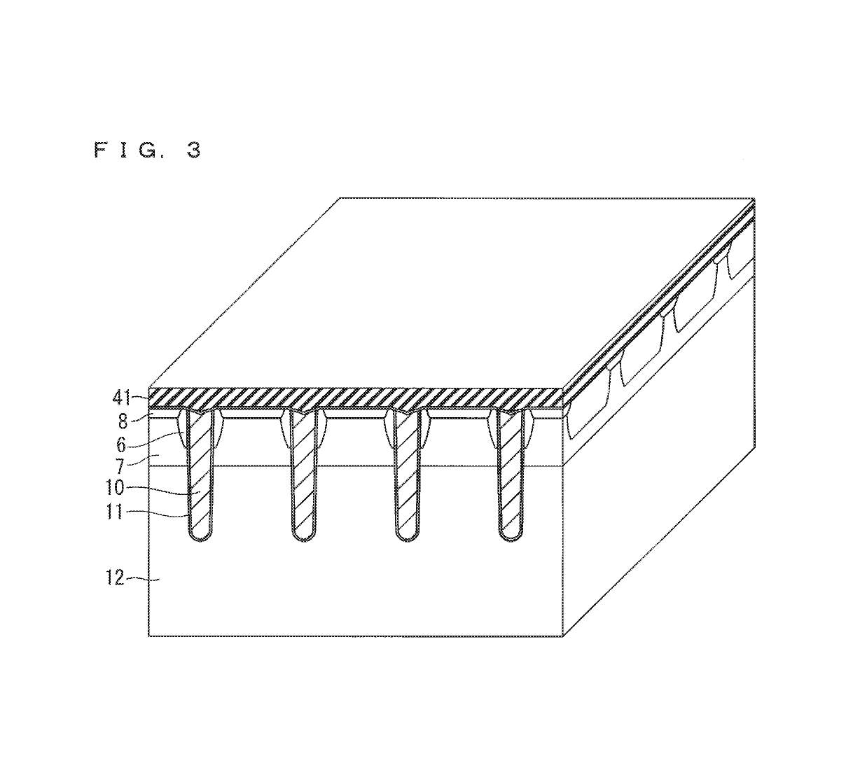

Next, in a step shown in FIG. 3, a silicon oxidation film 41 is formed on the entire upper main surface of the semiconductor substrate 12 by, for example, the CVD.

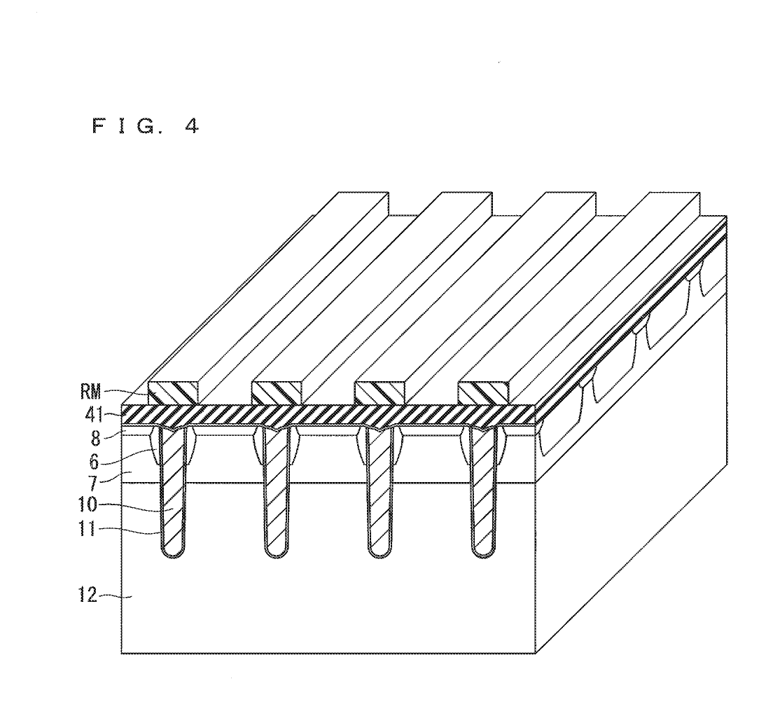

Next, in a step shown in FIG. 4, a resist pattern RM that covers the silicon oxidation film 41 corresponding to upper portions of the trench gate electrodes 10, an upper portion of the impurity layer 6, and an upper portion of a region in contact with the impurity layer 6 and the impurity layer 8 and that has a stripe shape is formed by photolithography.

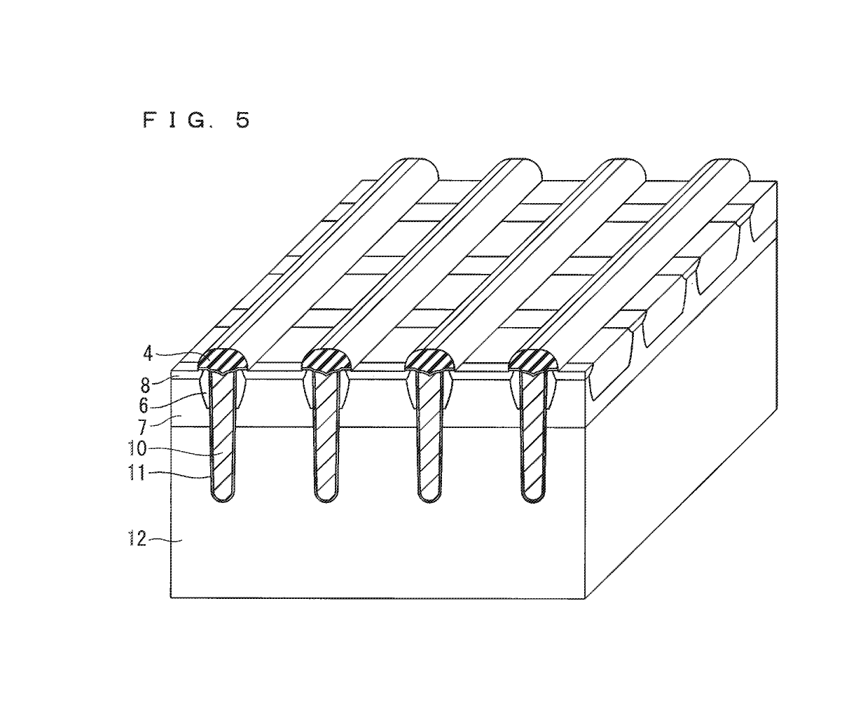

Next, the silicon oxidation film 41 is etched with the resist pattern RM as an etching mask to form the contact interlayer insulating film 4 having a stripe shape as shown in FIG. 5.

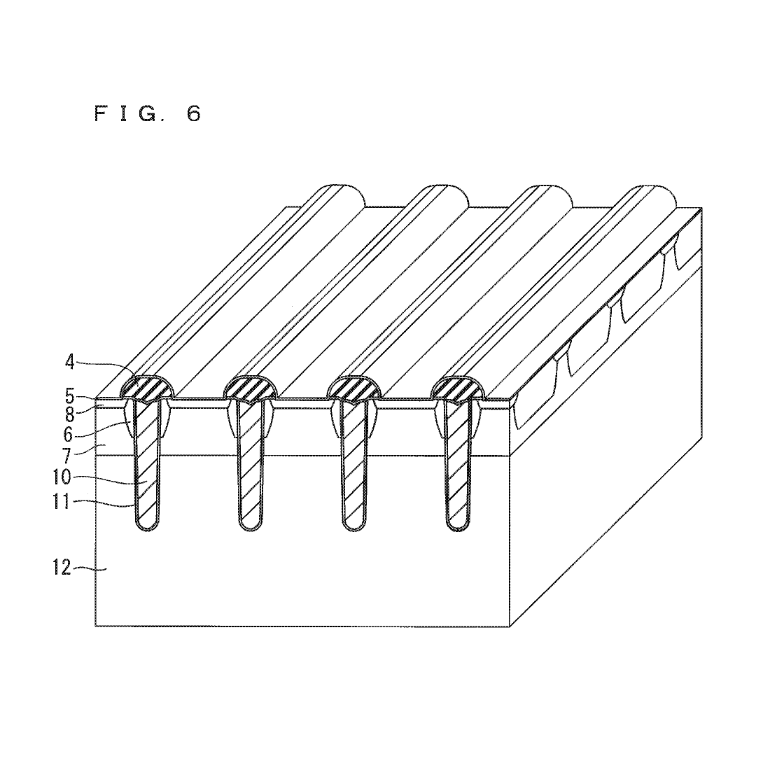

Next, in a step shown in FIG. 6, after a metal film of Ti or Co is formed by, for example, sputtering on the entire surface of the semiconductor substrate 12 including the contact interlayer insulating film 4 formed thereon, the metal film is heated by a lamp anneal to be made into silicide, to thereby form the barrier metal 5.

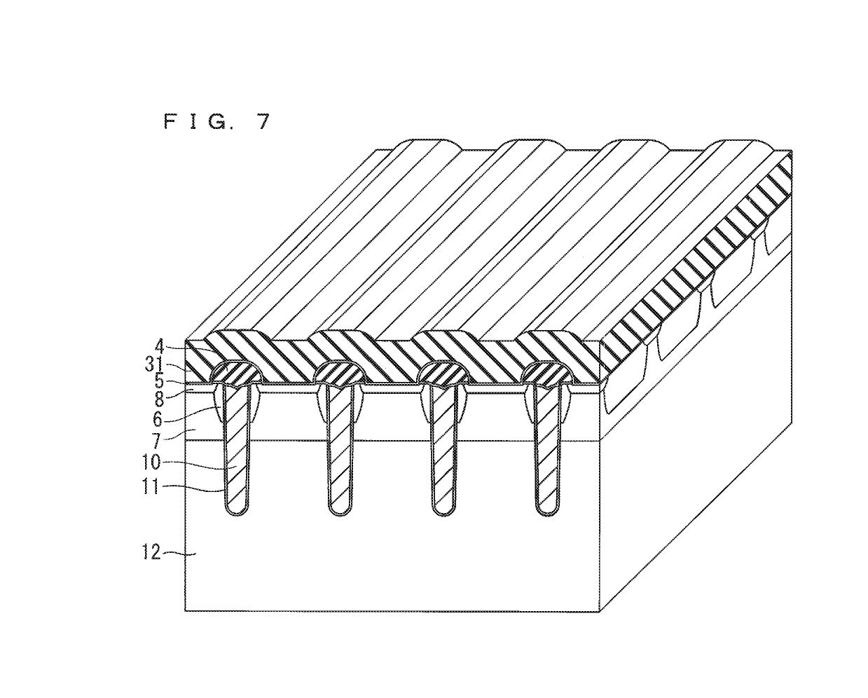

Next, in a step shown in FIG. 7, a metal film 31 made of any of W, Al, AlSi, AlSiCu, and AlCu is formed by, for example, the sputtering, PVD, or the CVD on the entire surface of the semiconductor substrate 12 including the barrier metal 5 formed thereon. The metal film 31 has a thickness that completely covers the contact interlayer insulating film 4, the thickness being 200 nm to 600 nm, for example. Thus, the metal film 31 is completely buried in the portions between the projecting portions of the contact interlayer insulating film 4.

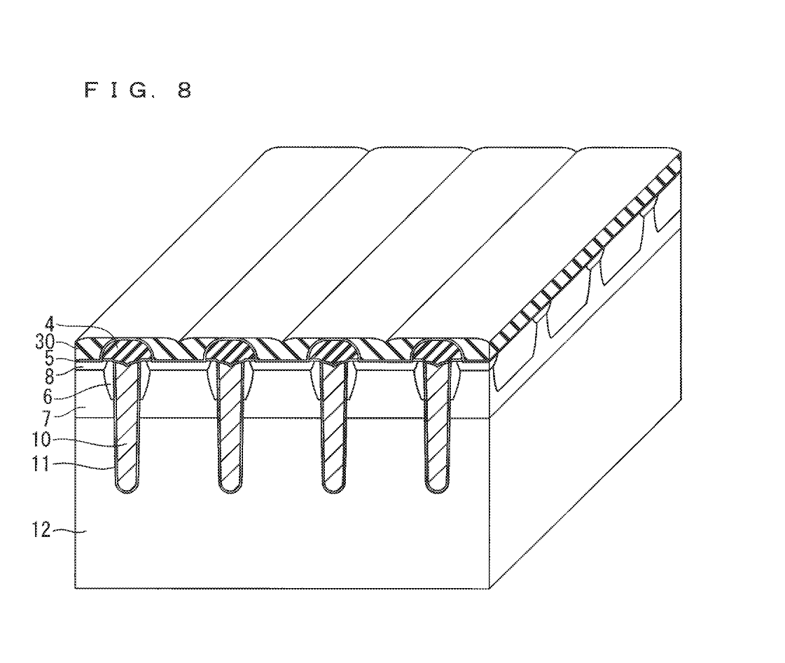

Next, in a step shown in FIG. 8, the metal film 31 is planarized by reducing, through etching, the thickness that has been formed, to thereby form the planarized buried film 30. Thus, the planarized buried film 30 is completely buried in the portions between the projecting portions of the contact interlayer insulating film 4 on the semiconductor substrate 12 to resolve the irregularities due to the contact interlayer insulating film 4.

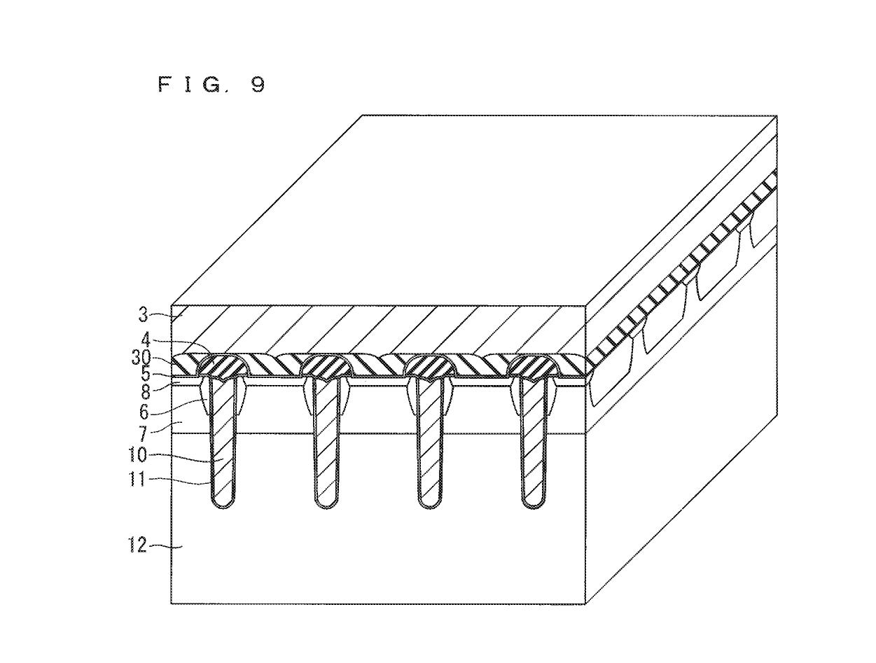

Next, in a step shown in FIG. 9, a metal film made of any of Al, AlSi, AlSiCu, and AlCu is formed on an entire surface of the planarized buried film 30 by, for example, the sputtering, the PVD, or the CVD, to thereby form the contact electrode 3. In this case, the planarized buried film 30 is planarized, so that the contact electrode 3 has excellent coverage, and the planarized contact electrode 3 having the uniform thickness can be obtained.

The planarized buried film 30 and the contact electrode 3 are formed of the same metal, thereby obtaining compatible bonding.

The metal film 31 has a thickness set to, for example, 3.0 μm or more, which allows the remains of a sufficient thickness when the contact electrode 3 is etched by a plating treatment.

Furthermore, the contact electrode 3 is heat-treated at a temperature of 400° C. or higher in a manufacturing process, so that a step height of the irregularities is 2.0 μm or less.

In other words, after the contact electrode 3 (contact electrode 15), which is made of Al as a main component, is formed by the PVD, a heat treatment at the melting point (approximately 660° C.) or lower of Al causes constituent atoms in a solid-phase state to spread and aggregate, and a growth of grains and a reflow (reduction) of irregularities on the surface can be seen. This also improves mechanical strength.

When the planarized buried film 30 is made of W, the irregularities on the surface of the contact electrode 3 are almost 0 (at the level that can be ignored).

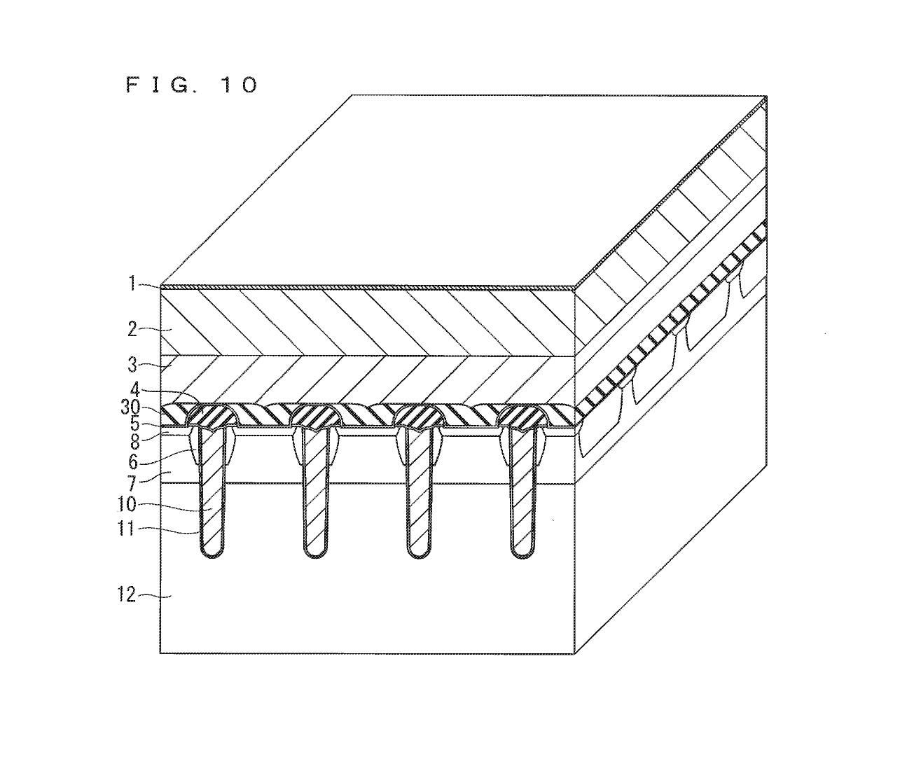

Next, in a step shown in FIG. 10, the junction electrode 2 and the oxidation preventing film 1 are formed in the stated order on an entire surface of the contact electrode 3 by the plating.

Subsequently, the metal film 151 and the metal film 152 are formed in the stated order on the entire lower main surface of the semiconductor substrate 12 by the plating to form the contact electrode 15 having the multiple layers, and furthermore, the junction electrode 16 and the oxidation preventing film 17 are formed in the stated order on the entire surface of the metal film 152 by the plating, so that the trench-gate MOS transistor 100 shown in FIG. 1 is obtained.

Here, the metal film 151 is made of any of Al, AlSi, AlSiCu, and AlCu, for example, and has a thickness of 2.0 μm to 6.0 μm, and the metal film 152 is made of Ti or V, for example, and has a thickness of 0.02 μm to 0.1 μm.

The contact electrode 15 may be formed as a three-layer film. In that case, on the semiconductor substrate 12, for example, Ti or V having a thickness of 0.02 μm to 0.1 μm is formed as a first layer, for example, any of Al, AlSi, AlSiCu, and AlCu having a thickness of 2.0 μm to 6.0 μm is formed as a second layer, and for example, Ti or V having a thickness of 0.02 μm to 0.1 μm is formed as a third layer.

The contact electrode 15 may be formed as a single-layer film, and in that case, AlSi having a thickness of 2.0 μm to 6.0 μm is formed.

<Installation to Semiconductor Device Module>

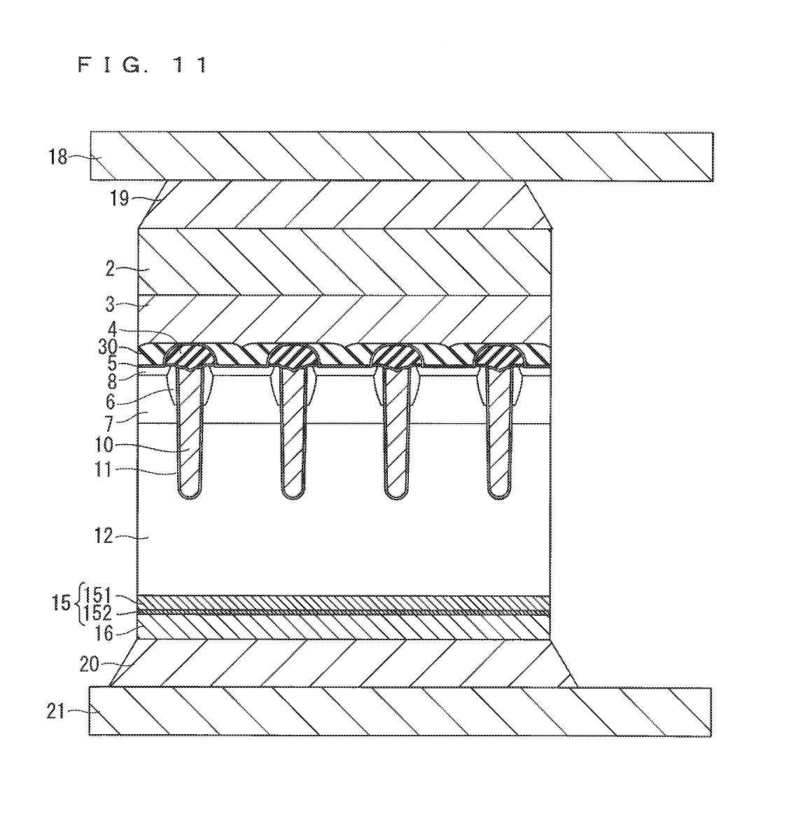

Lastly, FIG. 11 shows a state in which the trench-gate MOS transistor 100 is installed in a semiconductor device module.

As shown in FIG. 11, the junction electrode 2 and the junction electrode 16 are respectively bonded to a junction electrode 18 and a junction electrode 21 of the semiconductor device module through a solder layer 19 and a solder layer 20, the junction electrodes 18, 21 being opposite to the junction electrodes 2, 16, respectively. The oxidation preventing film 1 on the junction electrode 2 is lost by the bonding, and the junction electrode 2 also has the thickness reduced by the bonding. The same applies to the junction electrode 16 and the oxidation preventing film 17.

As shown in FIG. 11, in the trench-gate MOS transistor 100, the planarized buried film 30 is buried in the portions between the projecting portions of the contact interlayer insulating film 4 on the semiconductor substrate 12, which planarizes the upper surface. Thus, in a case where the semiconductor module is bonded from the junction electrode 2 side, the stress acting on the inside of the contact electrode 3 due to mechanical and thermal factors from the module side does not cause the contact structure at the bottom of the contact electrode 3 to be affected by the anchor effect, and the stress is uniformly distributed, thereby improving the reliability of the bonding.

The junction electrode 2 is covered with the oxidation preventing film 1 of metal to prevent oxidation, but the oxidation preventing film 1 also causes deterioration of solder wettability. Moreover, rare metals such as Au, Ag, Pd, and Ti are used for the oxidation preventing film 1, so that a manufacturing cost increases with a greater thickness.

However, in the trench-gate MOS transistor 100, the contact electrode 3 being the underlying layer is planarized, which also planarizes the junction electrode 2, so that the oxidation preventing film 1 having a thin thickness can cover the surface of the junction electrode 2, allowing for improved solder wettability and a reduced manufacturing cost.

In addition, according to the present invention, the above preferred embodiments can be arbitrarily combined, or each preferred embodiment can be appropriately varied or omitted within the scope of the invention.

While the invention has been shown and described in detail, the foregoing description is in all aspects illustrative and not restrictive. It is therefore understood that numerous modifications and variations can be devised without departing from the scope of the invention.

What is claimed is:

1. A semiconductor device, comprising:
a semiconductor substrate;
a plurality of trench gate electrodes that reach the inside of said semiconductor substrate from one main surface of said semiconductor substrate, have a stripe shape in plan view, and are located in parallel with each other at an interval;
a gate insulating film located on surfaces of said trench gate electrodes;
a first impurity layer located in an upper layer portion of said semiconductor substrate;
a second impurity layer that is selectively located in a surface of said first impurity layer and is in contact with said gate insulating film;
an interlayer insulating film that is located so as to cover upper portions of said trench gate electrodes and an upper portion of said second impurity layer, projects on said semiconductor substrate, and has a stripe shape in plan view;
a planarized buried film of metal that is buried in portions between projecting portions of said interlayer insulating film on said semiconductor substrate and has an upper surface planarized;
a contact electrode located on said planarized buried film; and
a junction electrode located on said contact electrode.

2. The semiconductor device according to claim 1, wherein a step height of irregularities of said contact electrode is 2.0 μm or less.

3. The semiconductor device according to claim 1, wherein said planarized buried film is formed of any one of materials of W, Al, AlSi, AlSiCu, and AlCu.

4. The semiconductor device according to claim 1, wherein said contact electrode is formed of any one of materials of Al, AlSi, AlSiCu, and AlCu.

5. The semiconductor device according to claim 1, further comprising a third impurity layer selectively located in a surface of said first impurity layer between said trench gate electrodes.

6. A method for manufacturing semiconductor device according to claim 1, said method comprising the steps of;
(a) forming said interlayer insulating film so as to cover the upper portions of said trench gate electrodes and the upper portion of said second impurity layer and to cause said interlayer insulating film to project on said semiconductor substrate;
(b) forming a metal film so as to bury the portions between the projecting portions of said interlayer insulating film on said semiconductor substrate;
(c) planarizing said metal film by reducing an entire thickness of said metal film through etching to form said planarized buried film;
(d) forming said contact electrode on said planarized buried film by sputtering or PVD; and
(e) forming said junction electrode on said contact electrode by plating.

7. The method for manufacturing semiconductor device according to claim 6, wherein said step (b) includes the step of forming said metal film having a thickness of 3.0 μm or more.

8. The method for manufacturing semiconductor device according to claim 6, wherein said step (d) includes the step of heat-treating said contact electrode at a temperature of 400° C. or higher.
